(19) United States
(12) Patent Application Publication
(10) Pub. No.: US 2010/0006135 A1
(43) Pub. Date: Jan. 14, 2010

(54) THIN-FILM PHOTOVOLTAIC DEVICE MODULE AND FABRICATION METHOD THEREOF

(76) Inventors: Bum-Sung Kim, Seoul (KR); Seh-Won Ahn, Seoul (KR); Young-Joo Eo, Seoul (KR); Heon-Min Lee, Seoul (KR)

Correspondence Address: BIRCH STEWART KOLASCH & BIRCH, PO BOX 747, FALLS CHURCH, VA, 22040-0747, US

(21) Appl. No.: 12/294,259

(22) PCT Filed: Jan. 9, 2008
(86) PCT No.: PCT/KR08/00122

§ 371 Date: Dec. 17, 2008

(51) Int. Cl. H01L 31/042; H01L 31/18

(52) U.S. Cl. 136/244; 438/73; 257/E21.085

(57) ABSTRACT

A photovoltaic device module and a fabrication method thereof are disclosed. There are provided a solar cell module structure effective to prevent the performance of the overall module from being degraded when photoelectric conversion efficiency of a specific portion cell is degraded in a solar cell module in which solar cells are integrated, and a fabrication method thereof. More particularly, there are provided a module structure having two terminal wirings, in which one of them is formed by selecting and connecting at least two unit cells from a plurality of unit cells electrically connected and the other is formed by selecting and connecting at least two unit cells differentiated from the said selected unit cells., and a fabrication method thereof.

### TECHNICAL FIELD

The present invention relates to a photovoltaic device module and a fabrication method thereof. More particularly, the present invention includes a photovoltaic device module structure having two terminal wirings, in which one of them is formed by selecting and connecting at least two unit cells from a plurality of unit cells electrically connected and the other is formed by selecting and connecting at least two unit cells differentiated from the said selected unit cells, and a fabrication method thereof.

### BACKGROUND ART

In general, a solar cell is one of photovoltaic devices.

A photovoltaic device is a clean energy source for producing energy by converting light energy transferred from the Sun to the Earth into electric energy. A lot of research has been actively conducted into photovoltaic devices for many years.

The 70's oil crisis, the serious concern about the greenhouse effect due to carbon dioxide which started in the early 90's, and the resulting international agreements for mitigating global warming in the late 90's, as well as the sudden increase of oil prices in the 2000's, and the like have become an important motive for notifying humans of the necessity of a clean energy source such as a photovoltaic power generation system.

Solar cell materials studied so far are group-IV materials such as single-crystal silicon, poly-crystal silicon, amorphous silicon, amorphous SiN, amorphous SiGe, amorphous SiSn, and the like, group III-V compound semiconductors of GaAs, AlGaAs, InP, and the like, and group II-VI compound semiconductors of CdS, CdTe, Cu2S, and the like.

Moreover, studied solar cell structures are a pn structure including a backside electric field type, a p-i-n structure, a hetero-junction structure, a Schottky structure, a multi-junction structure including a tandem type or a vertical junction type, and the like.

### Disclosure of Invention

### Technical Problem

In general, the properties and the research and development required for solar cells are based on the improvement of photoelectric conversion efficiency, the reduction of fabrication cost, the reduction of the number of energy recovery years, and an increase in an area.

Solar cells using the single-crystal silicon or poly-crystal silicon have high photo-electric conversion efficiency, but have a problem in that the fabrication cost and the installation cost are high.

To address this problem, research and development are being conducted on a thin-film solar cell in which a material based on amorphous silicon is deposited on a flat glass or metal in multiple layers.

The thin-film solar cell is disadvantageous in that the photoelectric conversion efficiency is lower than that of a crystalline silicon solar cell, but is technically advantageous in that the photoelectric conversion efficiency may be improved in terms of a deposited material and a multi-layer cell structure, a large-area solar cell module can be produced at low fabrication cost, and the number of energy recovery years is short. In particular, since the fabrication cost of a substrate solar cell may be further reduced when a production rate increases in the large scale and with the automation of deposition equipment, research efforts are being directed theretoward.

In general, the thin-film solar cell module is obtained by dividing electrodes and photoelectric conversion semiconductor layers deposited on a substrate into unit cells and serially and parallel connecting the unit cells through a laser scribing method.

FIGS. 1 to 6 are cross-sectional views sequentially showing a conventional process for fabricating a thin-film solar cell module according to a prior art. FIGS. 7 to 9 are plan views of a partial solar cell in the process for fabricating the conventional thin-film solar cell module.

FIG. 1 shows a structure in which a transparent conductive oxide (TCO) layer 12 for fabricating a thin-film solar cell is disposed on a glass substrate 10.

FIG. 2 shows a result obtained by processing the TCO layer 12 with a laser for dividing it into unit cells through a laser scribing method. In this case, a plan view of the solar cell in the step of processing the TCO layer with the laser is shown in FIG. 7.

FIG. 3 is a cross-sectional view in which a semiconductor layer 14 having a p-i-n structure is disposed on an upper part of the TCO layer 12. The semiconductor layer 14 is possible in a single junction structure having one p-i-n structure, a double junction structure having two p-i-n structures, and a triple junction structure having three p-i-n structures.

FIG. 4 shows the step of processing the semiconductor layer 14 into the unit cells through the laser scribing method. FIG. 8 is a plan view of the step of processing the semiconductor layer 14 with the laser that corresponds to the step of FIG. 4.

FIG. 5 is a schematic view in which a backside electrode 16 constituted with a double structure of a metal layer or a TCO layer and a metal layer is disposed.

FIG. 6 shows the step of processing the backside electrode layer 16 for dividing it into the unit cells through a laser scribing method. In this case, the semiconductor layer is processed along with the backside electrode layer.

FIG. 9 is a plan view of the solar cell after the above-described processing steps.

FIGS. 10 to 12 are a plan view and an equivalent circuit view in which insulation properties are secured in a laser trimming process in which only the glass remains by removing an external deposition layer from the thin-film solar cell module after deposition and serial connection processes serving as conventional fabrication processes of the thin-film solar cell module according to the prior art are finished.

FIG. 10 is a plan view of the thin-film solar cell module, and FIG. 11 shows a diode equivalent circuit of a serially connected solar cell module.

This solar cell module structure has a problem in that an optical current should be generated in the same amount in all connected unit cells since solar cells are serially connected.

That is, when the optical current amounts generated in the respective unit cells are different from each other, there is a disadvantage in that the current is limited by a cell in which a generated current is small and the optical current generated from every cell is reduced, such that the efficiency of the overall solar cell module is lowered.

There is a problem in that a solar cell function of the overall module is lost when the performance is degraded, or the power generation capability is lost, due to an internal or external factor in a diode (indicated by the shaded area in the equivalent circuit) corresponding to a cell of a specific portion in the diode equivalent circuit of the conventional solar cell module of a serial array of FIG. 12.

Moreover, since a cell in which the generated optical current is small acts as a hot spot, there is a risk that heat is generated according to time lapse and a device is destroyed.

The problem may frequently occur in terms of performance degradation due to an external factor when the incidence of solar light is reduced by the shadow of a surrounding building, a leaf, dust, and the like covering a cell of a specific portion. In the fabrication process, partial cell performance may be also lowered by an internal factor such as partial contamination due to particles or the like.

To prevent the hot spot from being generated, a solar cell module in which a bypass diode is formed should be fabricated. However, it is difficult to fabricate the solar cell module of the above-described structure in the conventional thin-film module fabrication method.

Technical Solution

According to an aspect of the present invention, there is provided a thin-film photovoltaic device module comprising: two terminal wirings, in which one of them is formed by selecting and connecting at least two unit cells from a plurality of unit cells electrically connected and the other is formed by selecting and connecting at least two unit cells differentiated from the said selected unit cells.

Hereinafter, the unit cell indicates a photovoltaic device of a minimum unit, distinguishable from other cells, capable of receiving solar light and converting the solar light into electrical energy.

A electrical connection of the unit cells is a serial connection or a parallel connection. Specifically, in the present invention, the plurality of unit cells are arranged in at least two rows and at least two columns. At this time, preferably, a plurality of unit cells constituting the rows have the same area, thereby generating the same electromotive force.

In the present invention, the at least two rows formed by the unit cells are electrically connected in at least one form of a serial connection, a parallel connection, and a combination of the serial connection and the parallel connection. The number of rows is less than or equal to the number of columns.

A shape of the unit cells may be rectangular, but is not limited to a specific shape.

According to another aspect of the present invention, there is provided a method for fabricating a thin-film photovoltaic device module, comprising the steps of: forming a plurality of unit cells electrically connected; and forming two terminal wirings, in which one of them is formed by selecting and connecting at least two unit cells from a plurality of unit cells electrically connected and the other is formed by selecting and connecting at least two unit cells differentiated from the said selected unit cells.

In the present invention, the step of forming the plurality of unit cells comprises the steps of: forming a plurality of primary cells on a transparent conductive layer disposed on a substrate; disposing a semiconductor layer on the primary cells; forming a plurality of secondary cells on the semiconductor layer; disposing a backside electrode layer on the secondary cells; and forming a plurality of tertiary cells on the backside electrode layer and the semiconductor layer.

The formation of a plurality of primary, secondary and tertiary cells could be conducted by laser scribing method, and finally the plurality of tertiary cells could be defined as the plurality of unit cells electrically connected since only the plurality of tertiary cells are shown from outside.

The primary, secondary and tertiary cells form columns in a direction different from a row direction after row formation or a reverse order thereof is possible.

In the present invention, a trimming process is added before the step of forming the two terminal wirings in order to secure insulation properties of the thin-film photovoltaic device module.

A representative example of the photovoltaic device may include a solar cell.

The solar cell according to the present invention may form a bypass by performing the same laser process in a different direction from a laser process of the conventional solar cell module fabricated in a large area unit. Preferably, the different direction in the fabrication process is a right-angle direction. Serially arranged cells may be formed by this laser process in the direction perpendicular to the serial arrangement direction of the conventional solar cells.

In the present invention, the solar cell module is connected to diodes serially arranged in horizontal and vertical directions.

In row and column structures of the solar cell module of the present invention, the number of rows to be serially arranged is at least two and is less than or equal to the number of columns.

The laser process for a serial arrangement in the right-angle direction in the present invention, that is, the process for forming the unit cells in rows, may be performed simultaneously with the conventional laser process in the row direction. The laser process for the serial arrangement in the row direction after the conventional laser process in the column direction and vice versa are possible.

The laser process may include a laser scribing method preferably.

A specific process method for achieving a matrix structure of unit cells in the crosswise/horizontal and lengthwise/vertical directions can easily implement from a first function for rotating the solar cell itself by 90 degrees, a second function for bi-directionally driving a laser source in the right-angle direction thereof, a third function for simultaneously implementing a horizontal direction laser source and a vertical direction laser source, and a fourth function having a combination of the first to third functions.

A unit cell formation method of the present invention mainly uses a laser scribing method, but is not limited thereto. Those skilled in the art will appreciate that any well-known thin-film processing method can be used.

A wiring method of the solar cell module of the present invention may use both a method for wiring cells at both ends and a method for selecting and wiring specific cells, and includes two terminal wirings of which one is formed as one terminal by selecting and connecting at least two unit cells and the other is formed as the other terminal by selecting and connecting at least two unit cells different from the above-selected cells.

Advantageous Effects

The present invention can be applied to a solar cell module for implementing a bypass function to prevent properties of the overall module from being degraded due to performance degradation of a specific portion cell of a thin-film solar cell module.

Moreover, the present invention provides a method for fabricating a thin-film solar cell module that can implement a bypass function using only a semiconductor deposition process and a laser process for fabricating a thin-film solar cell without implementing the bypass function through a connection with a special bypass function device.

The present invention enables the bypass function using a conventional process without adding a special process to a method for fabricating a conventional solar cell module.

The present invention can be used in a method for fabricating a solar cell module that is compatible, practical, and directly applicable to present technology while implementing a bypass capable of preventing the performance of the overall solar cell from being degraded in a simplified process and directly maintaining an existing wiring method.

### BRIEF DESCRIPTION OF THE DRAWINGS

FIGS. 1 to 6 are cross-sectional views showing a conventional method for fabricating a thin-film solar cell module according to a prior art.

FIGS. 7 to 9 are plan views of a partial solar cell module in the conventional method for fabricating the thin-film solar cell module according to the prior art.

FIGS. 10 to 12 are a plan view and an equivalent circuit view of the conventional thin-film cell module according to the prior art.

FIGS. 13 to 16 are plan views showing a method for fabricating a thin-film solar cell module according to a first embodiment of the present invention.

FIGS. 17 and 18 are equivalent circuit views of the thin-film solar cell module according to the first embodiment of the present invention.

FIGS. 19 to 22 are plan views showing a method for fabricating the thin-film solar cell module according to a second embodiment of the present invention.

FIGS. 23 and 24 are equivalent circuit views of the thin-film solar cell module according to the second embodiment of the present invention.

FIG. 25 is a plan view of the thin-film solar cell module according to a third embodiment of the present invention.

FIG. 26 is an equivalent circuit view of the thin-film solar cell module according to the third embodiment of the present invention.

FIGS. 27 to 29 are views of two terminal wirings of the thin-film solar cell module according to the fourth embodiment of the present invention.

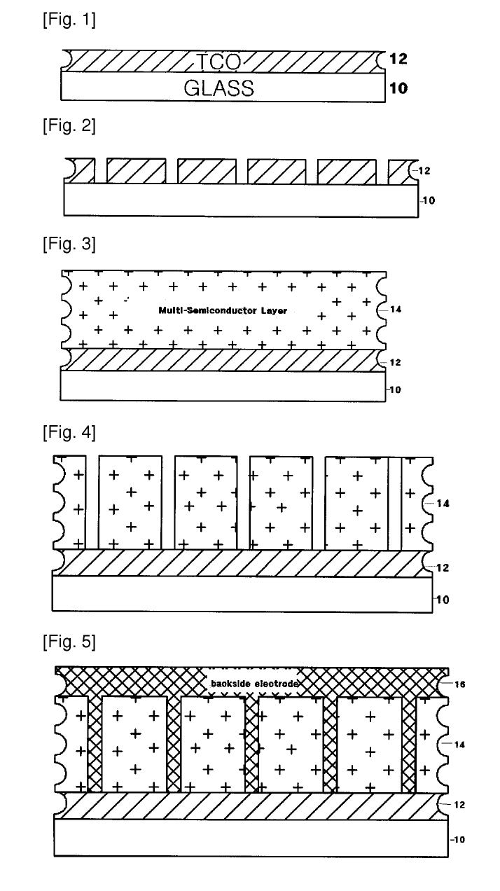

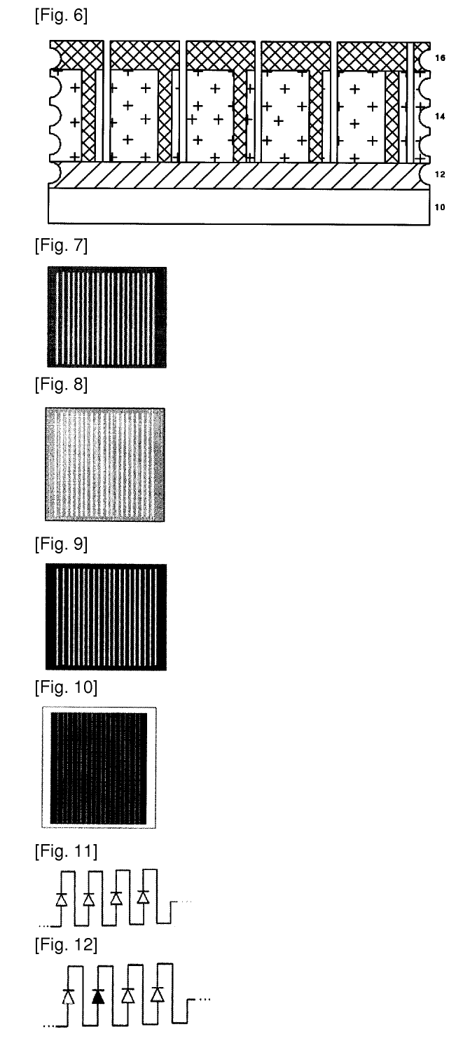

### BEST MODE FOR CARRYING OUT THE INVENTION

Hereinafter, preferred embodiments of the present invention will be described with reference to the accompanying drawings, and the present invention is not limited thereto.

Descriptions of well-known functions and constructions are omitted for clarity and conciseness.

In the present invention, a plurality of unit cells are configured. When one row is formed, an arrangement direction of the unit cells uses the terms column direction, horizontal direction, and crosswise direction. When a plurality of rows are formed, a row arrangement direction uses the terms row direction, vertical direction, and lengthwise direction.

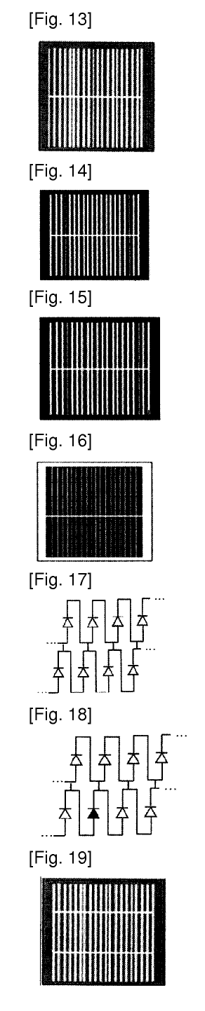

FIGS. 13 to 16 are plan views showing a method for fabricating a thin-film solar cell module according to a first embodiment of the present invention. Equivalent circuit views of the thin-film solar cell module according to the first embodiment of the present invention are shown in FIGS. 17 and 18.

Referring to FIGS. 13 to 16, the finished thin-film solar cell module has a structure in which unit cells are arranged in 2 rows and 19 columns. In this embodiment, 20 laser scribing processes of the conventional solar cell module are performed to form 19 cells in the column direction, that is, the horizontal direction, and one laser scribing process is performed in a right-angle direction to the column direction.

Referring to specific steps, FIG. 13 shows a result obtained by a process step of a transparent conductive oxide (TCO) layer corresponding to a first laser process step of the conventional solar cell module and one laser process of the TCO layer in the right-angle direction to a process direction.

FIG. 14 shows a result obtained by a process step of a semiconductor layer corresponding to a second laser process step of the conventional solar cell module and one laser process of the semiconductor layer in the right-angle direction to a process direction.

FIG. 15 is a plan view showing a result obtained by a process step of a backside electrode layer corresponding to a third laser process step of the conventional solar cell module and one additional laser process of the backside electrode layer in the right-angle direction. In this case, the backside electrode layer and the semiconductor layer are processed together.

FIG. 16 shows a solar cell module in which insulation properties at an edge is accomplished in a trimming process corresponding to the last laser process step of the conventional solar cell module.

FIGS. 17 and 18 show diode equivalent circuit views of a solar cell module capable of being obtained through a fabrication process of the solar cell module according to the first embodiment of the present invention. Serially connected diode arrangements are doubly overlapped by the number of unit cell rows.

This structure configures a two-dimensional (horizontal/vertical) serial arrangement diode equivalent circuit having a serial arrangement in both the horizontal direction and the vertical direction, which is different from the structure of the conventional solar cell module.

When performance is degraded, or power generation capability is lost, due to an internal or external factor in a specific portion of the solar cell module as shown in FIG. 18, a serial transmission can be performed in peripheral cells of a performance degradation portion (indicated by the shaded area in the figure) in a direction other than a diode direction in which a power generation function is degraded (or lost), such that a solar cell function of the overall module is not lost.

That is, referring to FIG. 18, power is generated through diodes arranged in a row of an upper stage without generating power in a column of a lower stage when the function of the diode indicated by the shaded area is lowered.

Referring to FIGS. 13 to 18, a right-angle direction laser process of the present invention, that is, a laser process for forming unit cells in two rows, is not necessarily performed in the center of the overall solar cell module. The present invention is not limited to this embodiment. Only the laser process is performed such that the unit cells configuring the respective rows have the same area so as to achieve the uniform electromotive force.

FIGS. 19 to 22 are step-by-step views showing a method for fabricating the thin-film solar cell module according to a second embodiment of the present invention. Equivalent circuit views of the thin-film solar cell module according to the above-described embodiment are shown in FIGS. 23 and 24.

Referring to FIGS. 19 to 22, the finished thin-film solar cell module has a structure in which unit cells are arranged in 3 rows and 19 columns. In this embodiment, 20 laser scribing processes of the conventional solar cell module are performed to form 19 cells in the column direction, that is, the horizontal direction, and 2 laser scribing processes are performed in a right-angle direction to the column direction.

Referring to specific steps, FIG. 19 shows a result obtained by a process step of a TCO layer corresponding to a first laser process step of the conventional solar cell module and 2 laser processes of the TCO layer in the right-angle direction to a process direction.

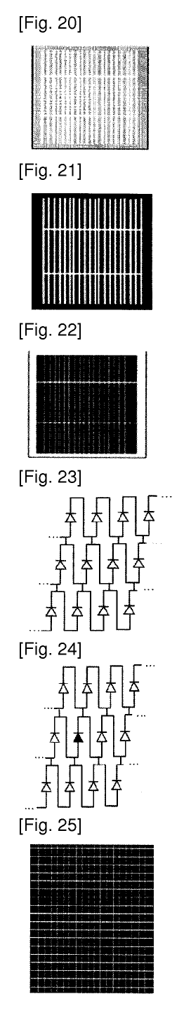

FIG. 20 shows a result obtained by a process step of a semiconductor layer corresponding to a second laser process step of the conventional solar cell module and 2 laser processes of the semiconductor layer in the right-angle direction to a process direction.

FIG. 21 is a plan view showing a result obtained by a process step of a backside electrode layer corresponding to a third laser process step of the conventional solar cell module and 2 additional laser processes of the backside electrode layer in the right-angle direction. In this case, the backside electrode layer and the semiconductor layer are processed together.

FIG. 22 shows a solar cell module in which insulation properties at an edge is secured in a trimming process corresponding to the last laser process step of the conventional solar cell module.

FIGS. 23 and 24 show diode equivalent circuit views of a solar cell module capable of being obtained through a fabrication process of the solar cell module according to the second embodiment of the present invention. Serially connected diode arrangements are triply overlapped by the number of unit cell rows.

This structure configures a two-dimensional (horizontal/vertical) serial arrangement diode equivalent circuit having a serial arrangement in both the horizontal direction and the vertical direction, which is different from the structure of the conventional solar cell module.

When performance is degraded, or power generation capability is lost, due to an internal or external factor in a specific portion of the solar cell module as shown in FIG. 24, a serial transmission can be performed in peripheral cells of a performance degradation portion (indicated by the shaded area in the figure) in a direction other than a diode direction in which a power generation function is degraded (or lost), such that a solar cell function of the overall module is not lost.

That is, referring to FIG. 24, power is generated through diodes arranged in a row of an upper or lower stage without generating power in a column of a center stage when the function of the diode indicated by the shaded area is lowered.

Referring to FIGS. 19 to 24, a right-angle direction laser process of the present invention, that is, a laser process for forming unit cells in three rows, does not equally divide the overall solar cell module. The present invention is not limited to this embodiment. Only the laser process is performed such that the unit cells configuring the respective rows have the same area so as to achieve uniform electromotive force.

The present invention is not limited to the above-described embodiment. The unit cells of the solar cell module can be arranged in at least two rows. Since a power generation area decreases as the number of rows increases, it is preferable that the number of rows of the unit cells is not greater than the number of columns.

FIG. 25 is a plan view of the thin-film solar cell module according to a third embodiment of the present invention, and shows the solar cell module configured with a column of 19 serially connected cells and a row of 19 serially connected cells fabricated in 18 column direction (or crosswise direction) laser process lines and 18 row direction (or lengthwise direction) laser process lines. As seen from the first and second embodiments shown in FIGS. 13 to 24, an unavailable area of a performance degradation portion due to an internal or external factor can be reduced when the number of vertical direction laser process lines of the present invention increases, that is, the number of rows configured with unit cells increases, thereby significantly contributing to secure the stability of the solar cell module.

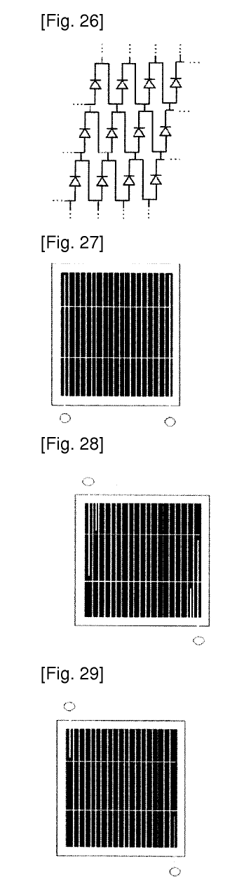

Specifically, FIG. 26 is an equivalent circuit view of the thin-film solar cell module according to the third embodiment of the present invention. The solar cell module having three rows configured in a unit cell arrangement has each unit cell whose area is reduced, but has a larger number of unit cells, in comparison with those of FIGS. 17 and 18 showing the equivalent circuit view of the solar cell module configured in two rows. Accordingly, it can be seen that the performance degradation of the overall solar cell is reduced when the diode function corresponding to one unit cell is lowered.

However, there can be predicted the adverse effect that a power generation area is reduced by a line width as the number of row direction laser process lines increases.

Accordingly, the number of row direction laser process lines in the present invention is limited to one or a value not greater than the number of serially arranged laser process lines of the conventional thin-film solar cell, that is, the number of column direction laser process lines.

Since the number of serially connected laser process lines of the column direction can increase or decrease according to a substrate size, the present invention is not limited to this embodiment.

Since a substrate can be rotated in terms of the directivity regarding a unit cell arrangement configuring the solar cell module in the present invention, the process sequence is possible in both the following cases.

First, after a laser process in the column direction, a laser process in the row direction corresponding to the right-angle direction thereof is possible. Second, after a laser process in the row direction, a laser process in the column direction corresponding to the right-angle direction thereof is possible.

A specific process method for implementing the solar cell module according to the present invention is possible as follows. The implementation can be facilitated in a first process using a rotation function of a stage itself on which the solar cell module or module is placed, a second process using a drive function in both the horizontal and vertical directions of a process laser source, a third process using a function for simultaneously driving a laser source dedicated for the horizontal direction and a laser source dedicated for the vertical direction, and a fourth process using a function having a combination of the first to third functions. However, the present invention is not limited to the above-described process method.

FIGS. 27 to 29 are views of two-terminal wirings of the thin-film solar cell module according to a fourth embodiment of the present invention, and show a wiring method of the solar cell module in which a bypass is implemented.

FIG. 27 shows a form of selectively connecting two terminals with one wiring by combining 3 unit cells at one end in the solar cell module configured with unit cells arranged in 3 rows and 19 columns.

FIG. 28 shows a form of selecting and wiring only a specific block portion of each row.

Moreover, FIG. 29 shows a form of selecting and wiring a specific unit cell.

The figures showing a method for wiring a specific block portion and a method for selecting and wiring a specific cell are only illustrative, and the present invention is not limited thereto. It is preferable that at least two unit cells are selected and wired to one terminal.

While the present invention has been shown and described with reference to preferred embodiments thereof, it will be understood by those skilled in the art that various changes and modifications may be made without departing from the spirit and scope of the present invention as defined by the appended claims.

### INDUSTRIAL APPLICABILITY

The present invention can be applied to a solar cell module for implementing a bypass function to prevent properties of the overall module from being degraded due to performance degradation of a specific portion cell of a thin-film solar cell module.

Moreover, the present invention provides a method for fabricating a thin-film solar cell module that can implement a bypass function using only a semiconductor deposition process and a laser process for fabricating a thin-film solar cell without implementing the bypass function through a connection with a special bypass function device.

The present invention enables the bypass function using a conventional process without adding a special process to a method for fabricating a conventional solar cell module.

The present invention can be used in a method for fabricating a solar cell module that is compatible, practical, and directly applicable to present technology while implementing a bypass capable of preventing the performance of the overall solar cell from being degraded in a simplified process and directly maintaining an existing wiring method.

1. A thin-film photovoltaic device module comprising:
two terminal wirings, in which one of them is formed by selecting and connecting at least two unit cells from a plurality of unit cells electrically connected and the other is formed by selecting and connecting at least two unit cells differentiated from the said selected unit cells.

2. The thin-film photovoltaic device module according to claim 1, wherein the electrical connection of the unit cells is a serial connection or a parallel connection.

3. The thin-film photovoltaic device module according to claim 1, wherein the plurality of unit cells are arranged in at least two rows and at least two columns.

4. The thin-film photovoltaic device module according to claim 3, wherein a plurality of unit cells constituting the rows have the same area.

5. The thin-film photovoltaic device module according to claim 3, wherein the at least two rows are electrically connected in at least one form of a serial connection, a parallel connection, and a combination of the serial connection and the parallel connection.

6. The thin-film photovoltaic device module according to claim 3, wherein the number of rows is less than or equal to the number of columns.

7. The thin-film photovoltaic device module according to claim 1, wherein a shape of the unit cells is rectangular.

8. A method for fabricating a thin-film photovoltaic device module, comprising the steps of:
forming a plurality of unit cells electrically connected; and
forming two terminal wirings, in which one of them is formed by selecting and connecting at least two unit cells from a plurality of unit cells electrically connected and the other is formed by selecting and connecting at least two unit cells differentiated from the said selected unit cells.

9. The method according to claim 8, wherein the step of forming the plurality of unit cells comprises the steps of:
forming a plurality of primary cells on a transparent conductive layer disposed on a substrate;
disposing a semiconductor layer on the primary cells;
forming a plurality of secondary cells on the semiconductor layer;
disposing a backside electrode layer on the secondary cells; and
forming a plurality of tertiary cells on the backside electrode layer and the semiconductor layer.

10. The method according to claim 9, wherein the primary, secondary and tertiary cells are formed in at least two rows and at least two columns.

11. The method according to claim 10, wherein the primary, secondary and tertiary cells form columns in a direction different from a row direction after row formation or form rows in a direction different from a column direction after column formation.

12. The method according to claim 11, wherein the different direction is a right-angle direction.

13. The method according to claim 10, wherein cells constituting the rows have the same area.

14. The method according to claim 10, wherein the number of rows is less than or equal to the number of columns.

15. The method according to claim 8, wherein a trimming process is added before the step of forming the two terminal wirings.
